(19) United States
(12) Patent Application Publication
(10) Pub. No.: US 2004/0218645 A1
(43) Pub. Date: Nov. 4, 2004

(54) Semiconductor laser device and method of producing the same, and optical disc unit

(75) Inventors: Shuichi Hirukawa, Nara-shi (JP); Hidenori Kawanishi, Oxford (GB); Kei Yamamoto, Nara-shi (JP)

Correspondence Address: Barry E. Bretschneider, Morrison & Foerster LLP, Suite 300, 1650 Tysons Boulevard, McLean, VA, 22102, US

(73) Assignee: SHARP KABUSHIKI KAISHA, Osaka-shi (JP)

(21) Appl. No.: 10/809,788

(22) Filed: Mar. 26, 2004

(30) Foreign Application Priority Data
Mar. 26, 2003 (JP) P2003-085112

(51) Int. Cl. H01S 5/00

(52) U.S. Cl. 372/45; 372/46

(57) ABSTRACT

In a semiconductor laser device having an oscillation wavelength of larger than 760 nm and smaller than 800 nm, on an n-type GaAs substrate (101), there are stacked in sequence an n-type first and second lower cladding layers (103, 104), a lower guide layer (105), a GaAs lower interface protective layer (106), an InGaAsP strained multiquantum well active layer (107), a GaAs upper interface protective layer (108), an upper guide layer (109) and a p-type upper cladding layer (110). An interface between the quantum well active layer (107) and the upper guide layer (109), and an interface between the quantum well active layer (107) and the lower guide layer (105) become steep, and also epitaxy growth of crystals becomes favorable.

This nonprovisional application claims priority under 35 U.S.C. §119(a) on Patent Application No. 2003-085112 filed in Japan on Mar. 26, 2003, the entire contents of which are hereby incorporated by reference.

### BACKGROUND OF THE INVENTION

The present invention relates to a semiconductor laser device and an optical disc unit, in particular to a semiconductor laser device that can realize high output and high reliability, and an optical disc unit using the same.

Semiconductor laser devices are used for optical communication devices, optical recording devices and so on. Recently, there are increasing needs for high speed and large capacity in such devices. In order to meet the demands, research and development has been advanced for improving various characteristics of semiconductor laser devices.

Among them, a 780 nm band semiconductor laser device, which is used for an optical disc unit such as a conventional CD or CD-R/RW, is usually made of an AlGaAs materials. Since demands for high-speed writing have been increasing also in the CD-R/RW, high-output semiconductor laser devices are requested in order to satisfy these demands.

As a conventional AlGaAs semiconductor laser device, there is one as shown in FIG. 11 (see, e.g., JP 11-274644 A). The structure of the AlGaAs semiconductor laser device will be briefly described. As shown in FIG. 11, on an n-type GaAs substrate 501, there are an n-type GaAs buffer layer 502, an n-type Al_{0.5}Ga_{0.5}As lower cladding layer 503, an Al_{0.35}Ga_{0.65}As lower guide layer 504, a multiquantum well active layer 505 composed of two Al_{0.12}Ga_{0.88}As well layers (each layer having a thickness of 80 521 ) and three Al_{0.35}Ga_{0.65}As barrier layers (each layer having a thickness of 50 Å) disposed alternately, an Al_{0.35}Ga_{0.65}As upper guide layer 506, a p-type Al_{0.5}Ga_{0.5}As first upper cladding layer 507 and a p-type GaAs etching stopper layer 508 that are stacked in this order. A mesa stripe-shaped p-type Al_{0.5}Ga_{0.5}As second upper cladding layer 509 and a eaves-shaped p-type GaAs cap layer 510 are sequentially formed on a surface of the etching stopper layer 508. An n-type Al_{0.7}Ga_{0.3}As first current blocking layer 511 and an n-type GaAs second current blocking layer 512 are stacked on both sides of the second upper cladding layer 509, so that regions other than the mesa stripe portion are defined as current constriction portions. A p-type GaAs planarizing layer 513 is formed on the second current blocking layer 512, and a p-type GaAs contact layer 514 is laid on the entire surface thereof.

The semiconductor laser device has a threshold current of 35 mA and a COD (Catastrophic Optical Damage) level of about 160 mW.

However, in the semiconductor laser device that employs the AlGaAs material, “end-face damage” caused by COD is liable to occur on laser light-emitting end faces during the high-power operation, due to influence of active Al (aluminum) atoms. As a result, such a semiconductor laser device only had a maximum optical output of about 160 mW. The end-face damage caused by COD is presumed to occur by the following mechanism. In the end faces of a resonator, because Al is easily oxidized, a surface level is formed thereby. Carriers injected into the active layer are relaxed through the level, when heat is emitted. Therefore, the temperature increases locally. The increase in the temperature reduces the bandgap of the active layer in the vicinity of the end faces. Carriers generated by absorption of laser light in the vicinity of the end faces of the active layer are relaxed again through the surface level to generate heat. It is considered that, by repeating such a positive feedback, the end faces are finally melted resulting in stop of oscillation. Since Al is contained in an active region in the conventional semiconductor laser device, the end-face damage becomes a big problem.

The present inventors have proceeded with the study on high-output semiconductor laser devices that employ InGaAsP materials that contain no Al (Al-free materials). Basically; in the Al-free materials, even if they have the same bandgap energy, values of a conduction band bottom energy level (Ec) and a valence band top energy level (Ev) vary. In the case where an InGaAsP material has a composition whose lattice constant is close to that of the GaAs substrate, the bandgap energy (Eg) extends to the valence band side. Therefore, when InGaAsP materials are used for well layers and barrier layers, even if a bandgap energy difference (ΔEg) between both layers is set to a large value, only a difference in Ev (|ΔEv|) increases and a sufficiently large difference in Ec (|ΔEc|) is not secured, compared with the AlGaAs semiconductor laser device. For that reason, an AlGaAs material layer is required outside the active region composed of well layers and barrier layers in a manner so as to secure a sufficiently large ΔEc and prevent an overflow of electrons. However, it is also necessary to suppress degradation of crystals, which is presumably attributable to the fact that the AlGaAs material is different from the material of the quantum well active layer.

### SUMMARY OF THE INVENTION

It is an object of the present invention to provide a semiconductor laser device that is highly reliable even in high-power operation and has a long lifetime, and an optical disc unit using the semiconductor laser device.

In order to achieve the above object, according to a first aspect of the present invention, there is provided a semiconductor laser device in which, on a GaAs substrate, there are stacked in sequence at least a lower guide layer, an InGaAsP quantum well active layer composed of one or a plurality of well layers and a plurality of barrier layers alternately disposed and an upper guide layer, wherein

the semiconductor laser device has an oscillation wavelength of larger than 760 nm and smaller than 800 nm, and

an interface protective layer is provided at least one of between the quantum well active layer and the upper guide layer and between the quantum well active layer and the lower guide layer.

According to the present invention, an interface between the quantum well active layer and the upper guide layer or an interface between the quantum well active layer and the lower guide layer, or both the interfaces thereof become steep. Also, epitaxy growth of crystals becomes favorable. Accordingly, it is possible to obtain a high-output semiconductor laser device using a GaAs substrate (in particular, a 780 nm band high-output semiconductor laser device for use of CD-R/RW) that has high reliability and a long lifetime in a high-output operation.

In one embodiment, the interface protective layer is formed of GaAs.

According to the embodiment, a stable thin semiconductor layer can be stacked on the GaAs substrate due to the interface protective layer, and an interface that favorably switchovers can be fabricated. Therefore, a semiconductor laser device which is highly reliable and which has a long lifetime in a high-output operation can be obtained.

In one embodiment, the interface protective layer has a thickness of not more than 30 Å.

According to the embodiment, because the interface protective layer hardly absorbs laser light having an oscillation wavelength of larger than 760 nm and smaller than 800 nm, an interface that favorably switchovers can be fabricated without deteriorating the characteristics of the semiconductor laser device. Accordingly, a semiconductor laser device which is highly reliable and which has a long lifetime in high-power operation can be obtained.

In one embodiment, the upper guide layer and the lower guide layer are formed of AlGaAs.

According to the embodiment, AlGaAs is disposed in a manner so as not to be immediately adjacent to the well layer where radiative recombination occurs. This makes it possible to ensure the reliability and, at the same time, sufficiently suppress an overflow of carriers by a conduction band bottom energy level (Ec) of AlGaAs and a valence band top energy level (Ev) of AlGaAs. Accordingly, a high-power semiconductor laser device having high reliability and a long lifetime is advantageously realized. Furthermore, since the interface protective layer is present between the quantum well active layer and the guide layer, it is possible to dispose AlGaAs, which constitutes the guide layer, and the quantum well active layer in a manner such that they are not in contact with each other, so that a distance between the well layer and AlGaAs can more be secured. Accordingly, the similar effect can be obtained.

In one embodiment, an Al mole fraction of the upper guide layer and the lower guide layer is more than 0.2.

According to the embodiment, the above effect can be realized more favorably.

In one embodiment, the well layer has a compressive strain.

According to the embodiment, the oscillation threshold current is reduced and this realizes a high-output semiconductor laser device which is highly reliable particularly in a 780 nm band and which has a long lifetime.

In one embodiment, a quantity of the compressive strain is not more than 3.5%.

According to the embodiment, the above effect is favorably obtained.

In one embodiment, the barrier layers have a tensile strain.

According to the embodiment, the strain quantity of the barrier layers compensates the compressive strain of the well layer and thus a strained quantum well active layer having more stable crystals is fabricated. Therefore, a semiconductor laser device with high reliability is realized.

In one embodiment, a quantity of an absolute value of the tensile strain is not more than 3.5%.

According to the embodiment, the above effect is favorably obtained.

According to a second aspect of the present invention, there is provided a method of producing a semiconductor laser device having at least an AlGaAs lower guide layer, an InGaAsP quantum well active layer composed of one or a plurality of well layers and a plurality of barrier layers alternately disposed and an AlGaAs upper guide layer on a GaAs substrate, the method comprising:

a first process in which the lower guide layer and a GaAs lower interface protective layer are sequentially crystal-grown at a first growth temperature;

a second process in which, after the first process, the growth is interrupted, and the growth temperature is lowered to a second growth temperature;

a third process in which, after the second process, the growth is resumed to sequentially grow the quantum well active layer and a GaAs upper interface protective layer;

a fourth process in which, after the third process, the growth is interrupted, and the growth temperature is raised almost to the first growth temperature; and

a fifth process in which, after the fourth process, the growth is resumed to grow the upper guide layer on the GaAs upper interface protective layer.

According to the method of producing the semiconductor laser device, the lower interface protective layer prevents oxidation of AlGaAs of the lower guide layer, and the quantum well active layer having a lower growth temperature than that of the lower guide layer can be grown. Furthermore, while the upper interface protective layer prevents re-evaporation of P due to an increase in the temperature within the quantum well active layer, the upper guide layer can be grown. Accordingly, a high-output semiconductor laser device having high reliability and a long lifetime is advantageously produced.

According to a third aspect of the present invention, there is provided an optical disc unit including the above semiconductor laser device.

According to the optical disc unit, the semiconductor laser device as described above operates with higher optical power than conventional. Therefore, data read-and-write operations are implementable even if the rotational speed of the optical disk is made higher than conventional. Accordingly, the access time to optical disks, which has hitherto mattered particularly in write operations, becomes much shorter than in a system using the conventional semiconductor laser device. This makes it feasible to provide an optical disk unit which is operable more comfortably.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross section of a semiconductor laser device according to a first embodiment of the present invention, taken along a plane perpendicular to a stripe direction of the device;

FIG. 2 is a cross section of the semiconductor laser device after completion of a first crystal growth and masking process, taken along the plane perpendicular to the stripe direction;

FIG. 3 is a cross section of the semiconductor laser device after completion of an etching process for forming a mesa stripe, taken along the plane perpendicular to the stripe direction;

FIG. 4 is a cross section of the semiconductor laser device after completion of a process of crystal growth for current blocking layers, taken along the plane perpendicular to the stripe direction;

FIG. 5 is a graph showing a relationship between an optical output and a current in a conventional semiconductor laser device and a semiconductor laser device according to the present invention;

FIG. 6 is a graph showing a difference in reliability between semiconductor laser devices due to the presence or absence of an interface protective layer;

FIG. 7 is a graph showing reliability of the semiconductor laser devices that depends on compressive-strain quantities of their well layers;

FIG. 8 is a graph showing a relationship between an Al mole fraction in a guide layer of the semiconductor laser device and a temperature characteristic (To);

FIG. 9 is a growth temperature profile of the semiconductor laser device according to the first embodiment of the present invention;

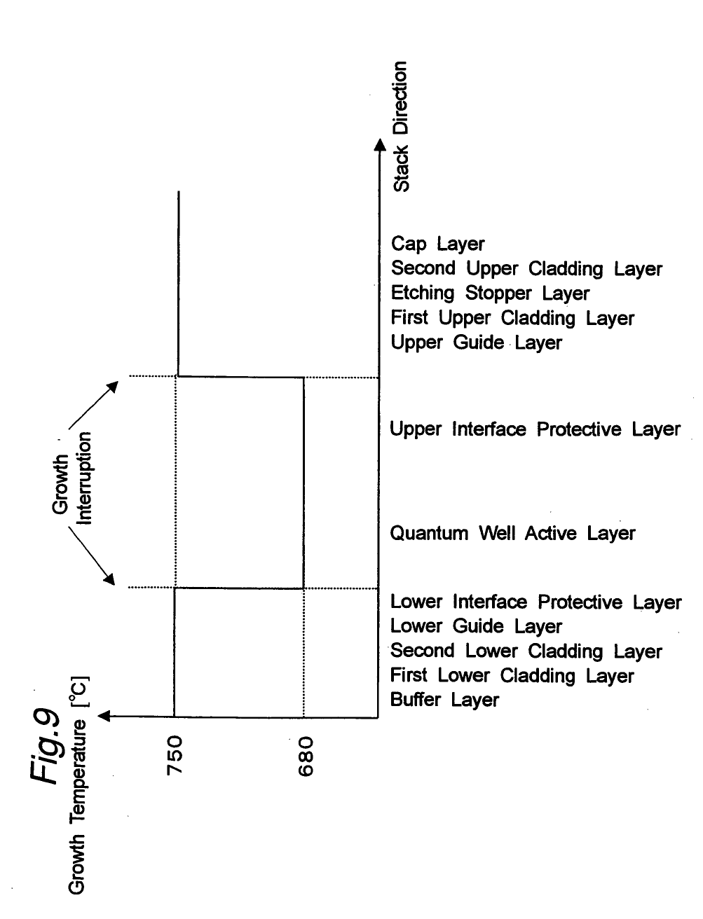

FIG. 10 is a schematic view of an optical disc unit according to a third embodiment of the present invention; and

FIG. 11 is a cross section of a conventional semiconductor laser device, taken along a plane perpendicular to a stripe direction of the device.

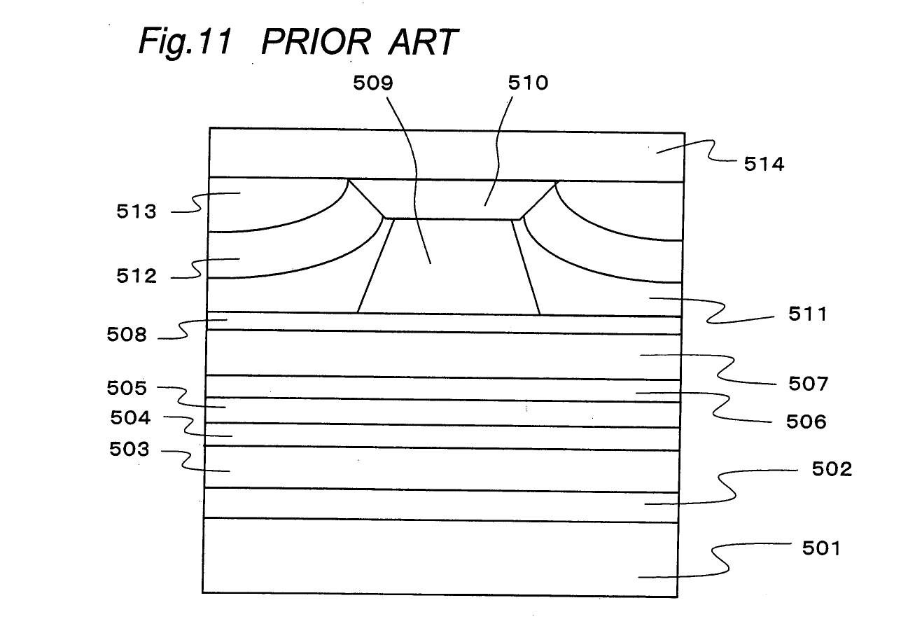

### DETAILED DESCRIPTION OF THE PREFERRED EMBODIMENTS

A semiconductor laser device, a method of producing the same and an optical disc unit of the present invention will hereinafter be described by embodiments illustrated.

### First Embodiment

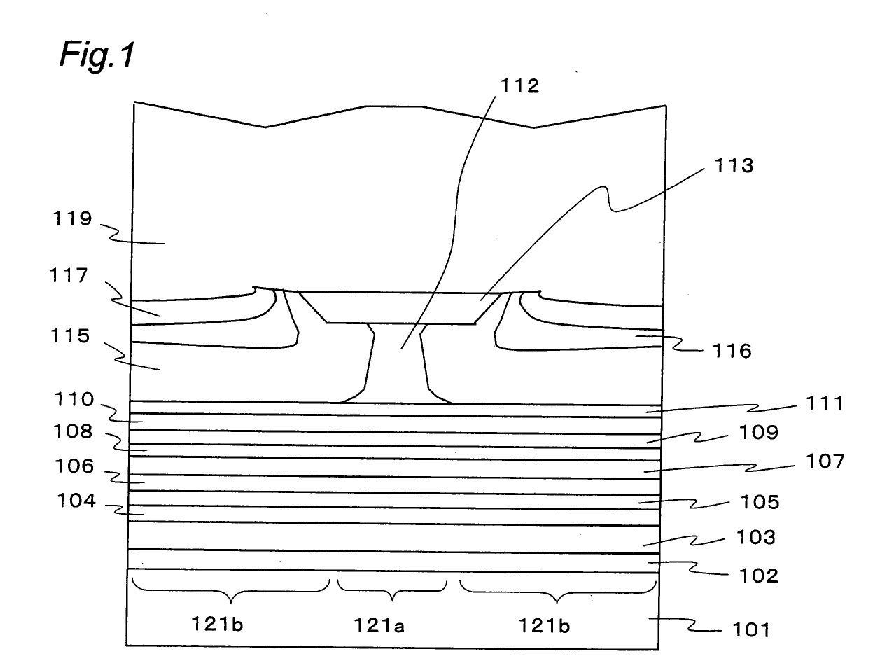

FIG. 1 is a view showing one example of the structure of a semiconductor laser device of the present invention. In this semiconductor laser device, on a surface of a semiconductor substrate, there are a buffer layer, a first conductive type semiconductor lower cladding layer, a quantum well active layer and a second conductive type semiconductor upper cladding layer that are stacked. A part of the upper cladding layer has a mesa-stripe shape. Both sides of the mesa-stripe portion are filled with a first and second conductive type semiconductor current blocking layers.

As shown in FIG. 1, on an n-type GaAs substrate 101, there are stacked in sequence an n-type GaAs buffer layer 102, an n-type AlGaAs first lower cladding layer 103, an n-type AlGaAs second lower cladding layer 104, an AlGaAs lower guide layer 105, a GaAs lower interface protective layer 106, a strained multiquantum well active layer 107, a GaAs upper interface protective layer 108, an AlGaAs upper guide layer 109, a p-type AlGaAs first upper cladding layer 110, and a p-type GaAs etching stopper layer 111. Also, on the etching stopper layer 111, there are provided a mesa stripe-shaped p-type AlGaAs second upper cladding layer 112 and a GaAs cap layer 113, and both sides of the mesa stripe-shaped p-type AlGaAs second upper cladding layer 112 and the GaAs cap layer 113 are filled with an n-type AlGaAs first current blocking layer 115, an n-type GaAs second current blocking layer 116, and a p-type GaAs planarizing layer 117, which layers define a light/current constriction area. Further, a p-type GaAs cap layer 119 is provided on the entire surface. The semiconductor laser device has a mesa stripe portion 121a and lateral portions 121b provided on both lateral sides of the mesa stripe portion 121a.

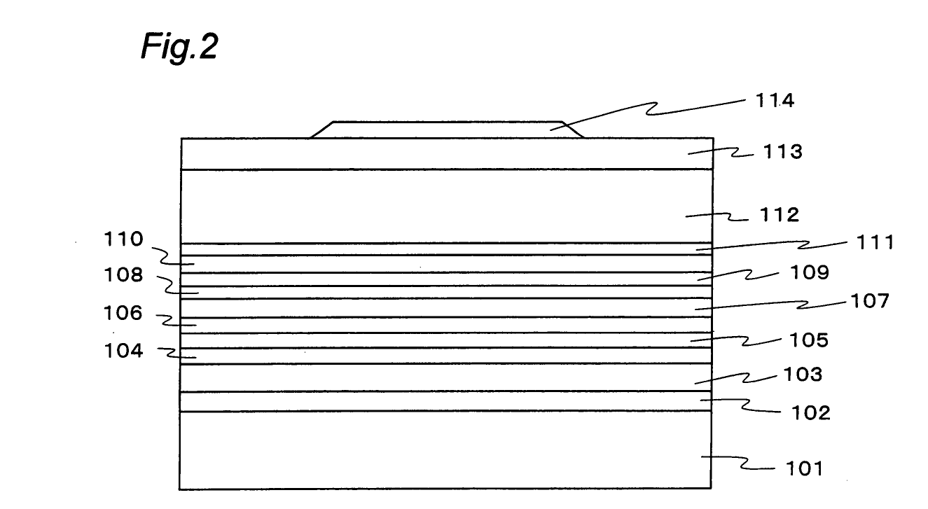

Next, with reference to FIGS. 2-4, a process for fabricating the semiconductor laser structure will be described. As shown in FIG. 2, on an n-type GaAs substrate 101 having a (100) plane, there are stacked in sequence an n-type GaAs buffer layer 102 (thickness of 0.5 μm), an n-type Al_{0.466}Ga_{0.534}As first lower cladding layer 103 (thickness of 3.0 μm), an n-type Al_{0.498}Ga_{0.502}As second lower cladding layer 104 (thickness of 0.18 μm), an Al_{0.433}Ga_{0.567}As lower guide layer 105 (thickness of 70 nm), a GaAs lower interface protective layer 106 (thickness of 10 Å), a strained multiquantum active layer 107 composed of two In_{0.2111}Ga_{0.7889}As_{0.6053}P_{0.3947} compressively strained well layers 107 (strain of 0.12%, each layer having a thickness of 80 Å) and three In_{0.0932}Ga_{0.9068}As_{0.4071}P_{0.5929} barrier layers (strain of ˜1.44%, the layers having.a thickness of 70 Å, 50 Å, 70 Å, respectively, from a substrate side) disposed alternately, a GaAs upper interface protective layer 108 (thickness of 10 Å), an Al_{0.433}Ga_{0.567}As upper guide layer 109 (thickness of 70 nm), a p-type Al_{0.4885}Ga_{0.5115}As first upper cladding layer 110 (thickness of 0.19 μm), a p-type GaAs etching stopper layer 111 (thickness of 30 Å), a p-type Al_{0.4885}Ga_{0.5115}As second upper cladding layer 112 (thickness of 1.28 μm) and a GaAs cap layer 113 (thickness of 0.75 μm) through crystal growth by metal organic chemical vapor deposition.

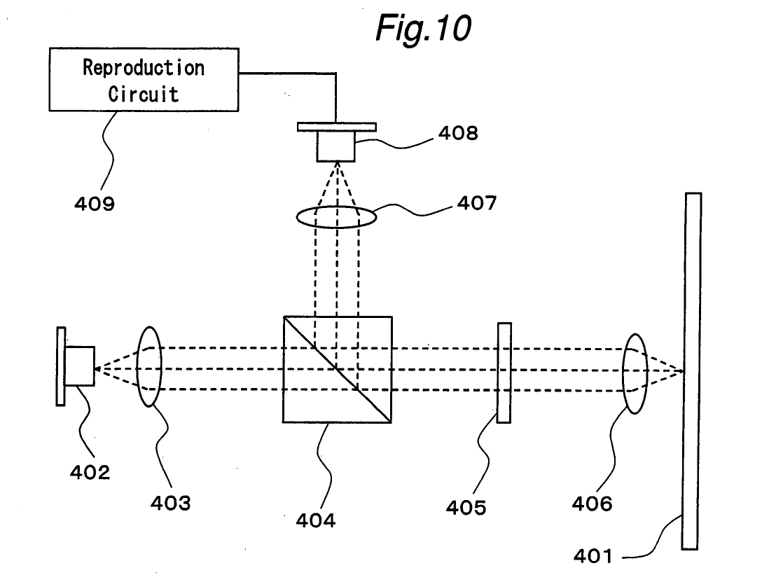

As shown in a growth temperature profile of FIG. 10, the growth temperature with the metal organic chemical vapor deposition is 750° C. from the buffer layer 102 to the lower interface protective layer 106. Then, the growth is interrupted, and the temperature is lowered to 680° C. Thereafter, the quantum well active layer 107 and the upper interface protective layer 108 are stacked in sequence. Subsequently, the growth is interrupted again, and the temperature is raised to 750° C., and then layers from the upper guide layer 109 to the cap layer 113 are stacked in sequence.

A method of producing a semiconductor laser device according to the present invention includes a first process in which the lower guide layer and the lower interface protective layer formed of GaAs are crystal grown at a first growth temperature of 750° C., a second process in which, after the first process, the growth is interrupted, and the growth temperature is lowered to a second growth temperature of 680° C., a third process in which, after the second process, the growth is resumed to sequentially grow the quantum well active layer 107 and the upper interface protective layer 108 formed of GaAs, a fourth process in which, after the third process, the growth is interrupted, and the growth temperature is raised to the first growth temperature of 750° C., and a fifth process in which, after the fourth process, the growth is resumed to grow the upper guide layer 109 on the upper interface protective layer 108.

Further, referring to FIG. 2, a resist mask 114 (mask width of 5.5 μm) is formed on a portion where a mesa-stripe portion is to be formed, by a photolithography process so that the mesa stripe portion will extend in the (011) direction.

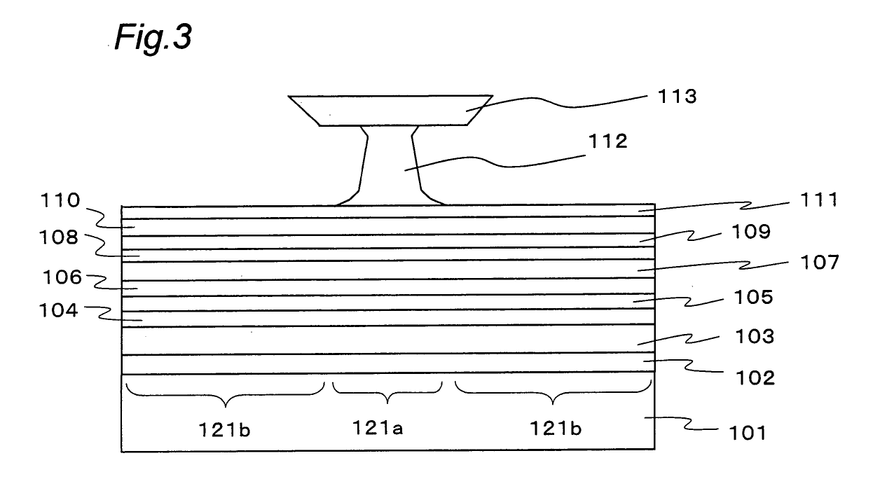

Next, as shown in FIG. 3, etching is applied to portions other than the resist mask 114 (shown in FIG. 2) to thereby form a mesa-stripe portion 121a. This etching is carried out in two steps using a mixed aqueous solution of sulfuric acid and hydrogen peroxide, and hydrofluoric acid, until immediately above the etching stopper layer 111. The fact that the etching rate of GaAs by hydrofluoric acid is low enables planarization of the etched surface and control of the width of the mesa stripe portion. The etching depth is 1.95 μm, and the mesa-stripe has a width of about 2.5 μm in its lowermost portion. After the etching, the resist mask 114 is removed.

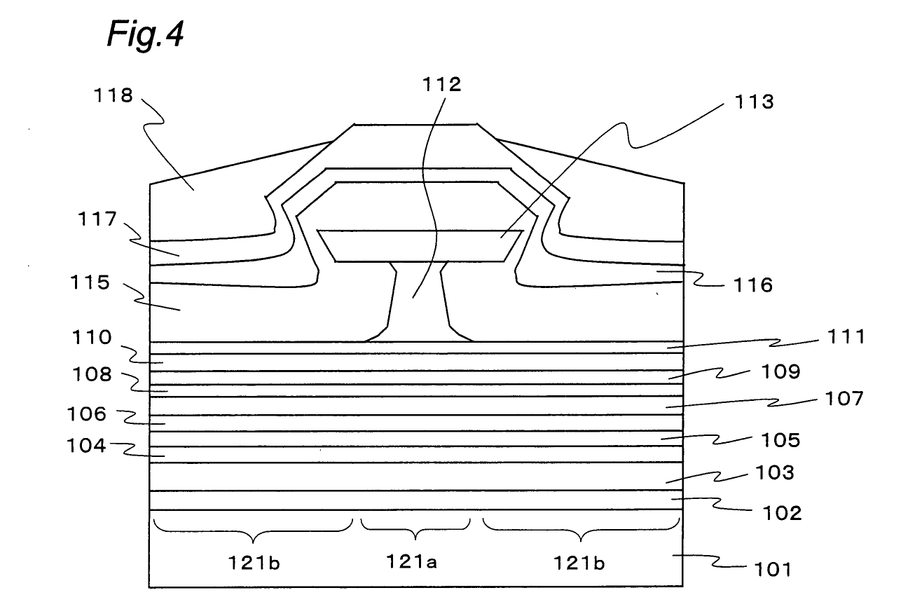

Subsequently, as shown in FIG. 4, an n-type Al_{0.7}Ga_{0.3}As first current blocking layer 115 (thickness of 1.0 μm), an n-type GaAs second current blocking layer 116 (thickness of 0.3 μm) and a p-type GaAs planarizing layer 117 (thickness of 0.65 μm) are sequentially crystal-grown by metal organic chemical vapor deposition to form a light/current constriction region.

After that, as shown in FIG. 4, a resist mask 118 is formed only on both the lateral portions 121b by the photolithography process. Subsequently, the current blocking layers above the mesa stripe portion 121a are removed by etching. The etching is carried out in two steps using a mixed aqueous solution of ammonia and hydrogen peroxide and a mixed aqueous solution of sulfuric acid and hydrogen peroxide.

Thereafter, the resist mask 118 is removed, and a p-type GaAs cap layer 119 (thickness of 2.0 μm), shown in FIG. 1, is formed. In this manner, a semiconductor laser device having the structure shown in FIG. 1 is fabricated.

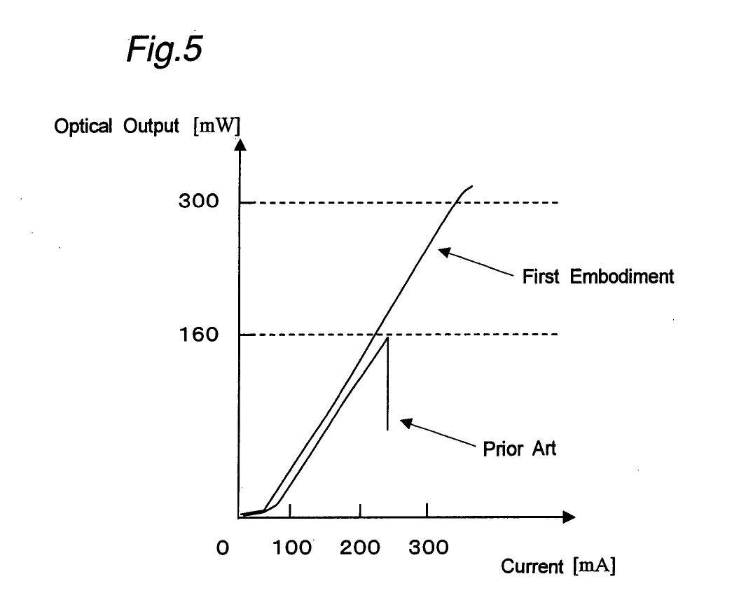

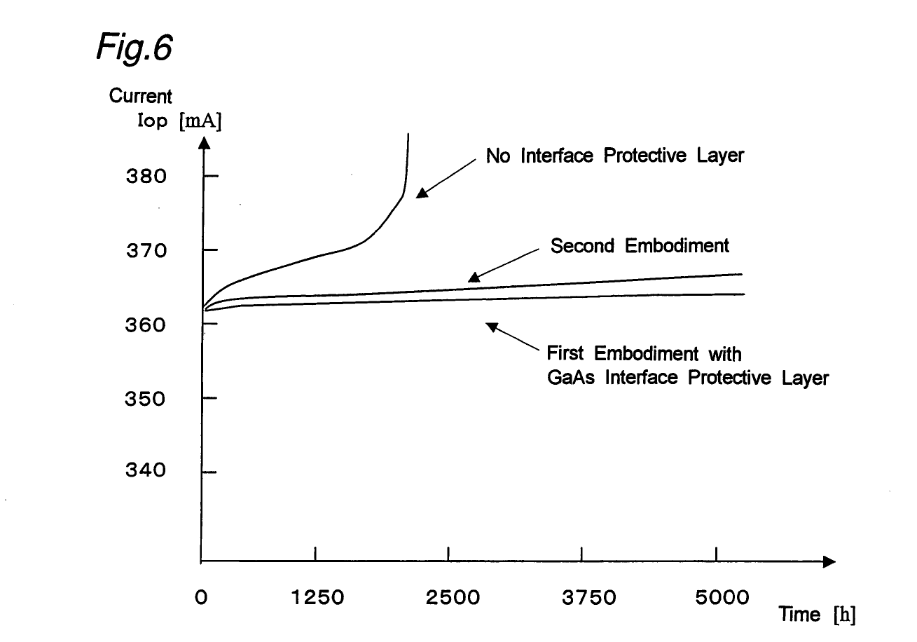

In the first embodiment, the oscillation wavelength was 780 nm. As seen from FIG. 5, stable operation wherein the COD level was 300 mW or more was confirmed in optical output-current characteristic tests. At the same time, as seen from FIG. 6, stable operation for 5000 hours or more was confirmed in reliability tests under the conditions of: a temperature of 70° C., and a pulse of 230 mW. In this manner, the present inventors have studied semiconductor laser devices that employ an InGaAsP quantum well active layer on the GaAs substrate. Consequently, a semiconductor laser device having a higher COD level compared with the one that employs AlGaAs was fabricated. This time, in order to further improve the lifetime and reliability of the semiconductor laser device in high-output operation, AlGaAs was used for the guide layers. Also, as to long-term deterioration of the characteristics caused by degradation of crystallinity at the interface of the AIGaAs guide layer and the InGaAsP barrier layer, which was presumably attributable to the growth interruption due to their respective different growth temperatures, the interface protective layer was provided, whereby an improvement in the characteristics was realized. More specifically, as in the first embodiment, after the lower AlGaAs guide layer and the GaAs lower interface protective layer were stacked, the growth was interrupted, and the growth temperature was lowered. After resuming the growth, the barrier layer is stacked on the GaAs lower interface protective layer so as not to be affected by the above-mentioned interface, which is presumed to lead to the improvement in the characteristics. Similarly, the provision of the GaAs upper interface protective layer between the barrier layer and the upper guide layer was also presumably led to an improvement in the characteristics. Referring to FIG. 6, Iop indicates current values when the output of the semiconductor laser device at 70° C. was 230 mW. For comparison, reliability tests were conducted under the same conditions except that no interface protective layer was provided. As a result, the end face damage occurred in a short time as shown in an upper side of FIG. 6.

In the first embodiment of the present invention, if the thickness of the interface protective layer exceeds 30 Å, it absorbs light, with the result that the characteristics of the semiconductor laser device tend to deteriorate. Therefore, a thickness of not more than 30 Å makes it possible to obtain the effect of the improvement in the characteristics as above.

In the first embodiment, the upper guide layer is formed of AlGaAs. Thus, the effect of sufficiently suppressing an overflow of carriers is achieved by a conduction band bottom energy level (Ec) of AlGaAs and a valence band top energy level (Ev) of AlGaAs. At the same time, because AlGaAs of the upper guide is not immediately adjacent to the well layer where radiative recombination occurs, reliability is secured. When producing an Al-free semiconductor laser device in order to obtain high reliability, all the layers including guide layers and cladding layers are usually made Al-free using InGaP and so on. However, in the first embodiment, AlGaAs with an Al mole fraction of more than 0.2, by which a well-balanced conduction band energy difference (ΔEc) and valence band energy difference (ΔEv) from the well layer(s) formed of InGaAsP having an oscillation wavelength of 780 nm is obtained, is provided as the guide layers.

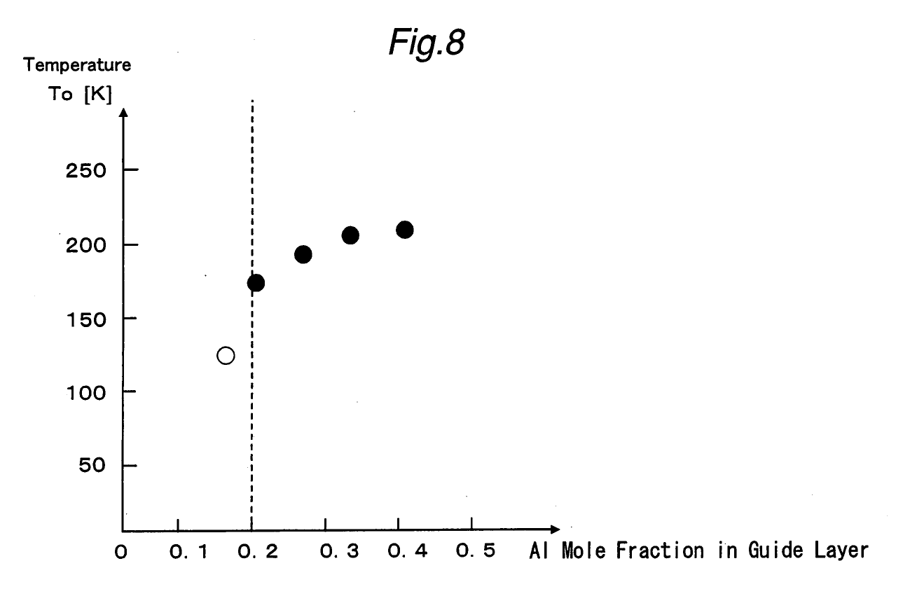

FIG. 8 is a graph showing the relationship between an Al mole fraction and a characteristic temperature (To). As shown in FIG. 8, it was confirmed that the temperature characteristics were improved in the case of the guide layer of AlGaAs in which the Al mole fraction was more than 0.2, so that sufficiently high reliability was achieved.

Since the compressively strained well layers formed of InGaAsP on the GaAs substrate are used in the first embodiment, the oscillation threshold current is reduced, whereby a semiconductor laser device which has high reliability in high-power operation particularly in the 780 nm band and which has a long lifetime is realized. Furthermore, since the compressive-strain quantity is not more than 3.5%, the above effect is optimally obtained. The strain quantity is herein represented by:

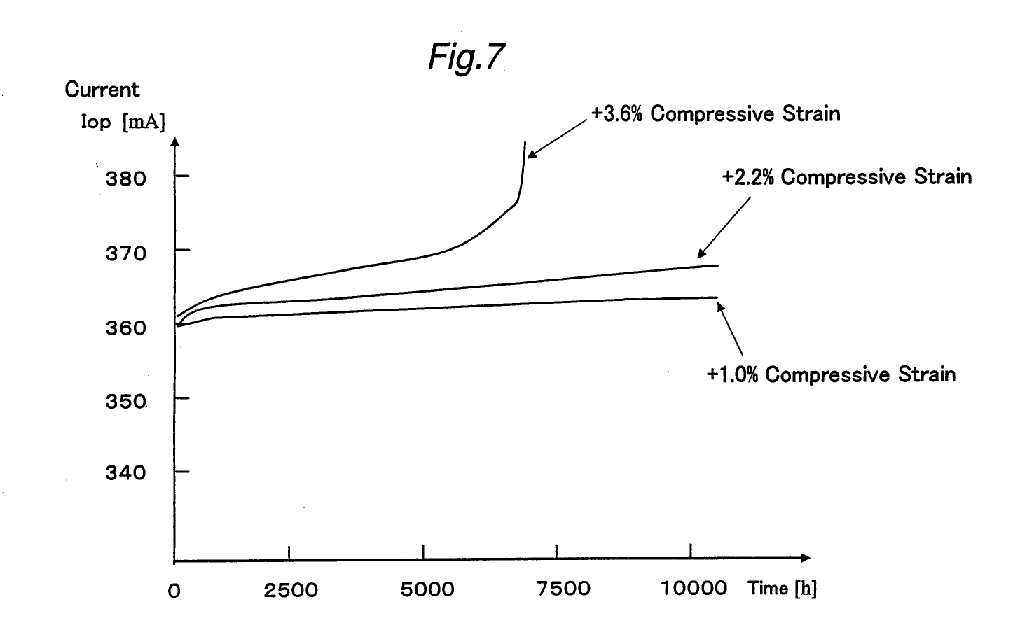

(a₁−a_{GaAs})/a_{GaAs}

where a_{GaAs} is a lattice constant of the GaAs substrate, and a₁ is a lattice constant of the well layer. If the value of the strain quantity is positive, the strain is called a compressive strain, and if the value is negative, it is called a tensile strain. FIG. 7 is a graph showing the reliability (70° C., 230 mW) of the semiconductor laser devices that depends on compressive-strain quantities of their well layers. It can be seen that if the compressive-strain quantity exceeds 3.5%, the reliability deteriorates. It is considered that this is attributable to deterioration of crystallinity due to an excessively large compressive-strain quantity.

Since the barrier layers each formed of InGaAsP and having a tensile strain are used in the first embodiment, they compensate the strain quantity of the well layers having a compressive strain, so that a strained quantum well active layer with more stable crystals can be fabricated. Consequently, a semiconductor laser device with high reliability can be realized. Furthermore, the tensile-strain quantity of not more than 3.5% makes it possible to obtain the above effect favorably.

Although the first embodiment has a buried ridge structure, the present invention is not limited thereto. The same effect may be achieved in any structure including ridge structure, internal stripe structure, and buried heterostructure. Although an n-type substrate is used in the first embodiment, the same effect may be achieved by using a p-type substrate and replacing the n type and the p type of the layers in the above embodiment. Although the wavelength of 780 nm is used, it is not limited thereto. The same effect may be achieved if the wavelength is more than 760 nm and less than 800 nm, namely, in the so-called 780 nm band.

Furthermore, although the thickness of the p-type GaAs cap layer 119 is set to approximately 2 μm, it may be formed to a larger thickness of approximately 50 μm. Further, the growth temperatures were set to 750° C. and 650° C., but they are not limited thereto. That is, the interface protective layer formed of GaAs is provided at the interface where the growth is interrupted. This optimizes growth temperatures of crystals so that a favorable crystal can be obtained for each material when forming a semiconductor laser structure including layers formed of a plurality of different materials through crystal growth, so that crystal growth can be performed at their optimized temperatures.

### Second Embodiment

A semiconductor laser device according to a second embodiment of the present invention has the same structure as that of the semiconductor laser device of the first embodiment, but crystal growth is performed at a fixed temperature. FIG. 1 also represents the semiconductor laser device in the second embodiment.

In the semiconductor laser device of the second embodiment, stable operation for 5000 hours or more was confirmed in reliability tests under the conditions of: an oscillation wavelength of 780 nm; a temperature of 85° C., and a pulse of 200 mW, as shown in FIG. 6.

In the second embodiment, because all the semiconductor layers are grown at 720° C., there is no growth interruption, different from the first embodiment. That is, it is considered that oxidation of AlGaAs, which is presumed to occur during the growth interruption, and re-evaporation of P, which is also presumed to occur during the growth interruption, are suppressed because there is no growth interruption itself. Furthermore, the temperature does not change at the interface of layers formed of different materials. Therefore, provision of the interface protective layer formed of GaAs for further improving steepness of the materials at the interface makes it possible to produce a semiconductor laser device having high reliability in high-power operation as well as having a long lifetime.

### Third Embodiment

FIG. 10 is a view showing an example of the structure of an optical disc unit that employs a semiconductor laser device according to the present invention. This optical disk unit operates to write data on an optical disk 401 or reproduce data written on the optical disk. In this optical disc unit, the semiconductor laser device 402 of the first embodiment is included as a light-emitting device for use in those operations.

This optical disk unit will be described in more detail. In this optical disk unit, for write operations, signal light emitted from the semiconductor laser device 402 passes through a collimator lens 403, becoming parallel light, and is transmitted by a beam splitter 404. Then, after its polarized state is adjusted by a λ/4 polarizer 405, the signal light is converged by an irradiation objective lens 406 to thereby irradiate the optical disk 401. For read operations, a laser beam with no data signal superimposed on the laser beam travels along the same path as in the write operation, irradiating the optical disk 401. Then, the laser beam reflected by the surface of the optical disk 401, on which data has been recorded, passes through the laser-beam irradiation objective lens 406 and the λ/4 polarizer 405, and is thereafter reflected by the beam splitter 404 so as for its traveling direction to be changed by 90°. Subsequently, the laser beam is focused by a reproduction-light objective lens 407 and applied to a signal-detection photodetector device 408. Then, in the signal-detection photodetector device 408, a data signal read from the optical disk 401 is transformed into an electric signal according to the intensity of the incident laser beam, and reproduced to the original information signal by a signal-light reproduction circuit 409.

The optical disk unit of the third embodiment employs the semiconductor laser device, as described above, which operates with higher optical power than conventional. Therefore, data read-and-write operations are implementable even if the rotational speed of the optical disk is increased to be higher than conventional. Accordingly, the access time to optical disks, which has hitherto mattered particularly in write operations, can be reduced to a large extent. This makes it feasible to provide an optical disk unit which allows more comfortable manipulation.

This embodiment has been described on a case where the semiconductor laser device of the present invention is applied to a recording and playback type optical disk unit. However, needless to say, the semiconductor laser device of this invention is applicable also to optical-disc recording units or optical-disc playback units using the 780 nm wavelength band.

The semiconductor laser device and the optical disc unit of the present invention should not be construed as being limited to the embodiments illustrated above. It is a matter of course that various modifications such as the number of well layers/barrier layers and thicknesses of such layers can be made without departing from the spirit of the invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device in which, on a GaAs substrate, there are stacked in sequence at least a lower guide layer, an InGaAsP quantum well active layer composed of one or a plurality of well layers and a plurality of barrier layers alternately disposed and an upper guide layer, wherein
the semiconductor laser device has an oscillation wavelength of larger than 760 nm and smaller than 800 nm, and
an interface protective layer is provided at least one of between the quantum well active layer and the upper guide layer and between the quantum well active layer and the lower guide layer.

2. The semiconductor laser device according to claim 1, wherein the interface protective layer is formed of GaAs.

3. The semiconductor laser device according to claim 2, wherein the interface protective layer has a thickness of not more than 30 Å.

4. The semiconductor laser device according to claim 1, wherein the upper guide layer and the lower guide layer are formed of AlGaAs.

5. The semiconductor laser device according to claim 4, wherein an Al mole fraction of the upper guide layer and the lower guide layer is more than 0.2.

6. The semiconductor laser device according to claim 1, wherein the well layer has a compressive strain.

7. The semiconductor laser device according to claim 6, wherein a quantity of the compressive strain is not more than 3.5%.

8. The semiconductor laser device according to claim 1, wherein the barrier layers have a tensile strain.

9. The semiconductor laser device according to claim 8, wherein a quantity of an absolute value of the tensile strain is not more than 3.5%.

10. A method of producing a semiconductor laser device having at least an AlGaAs lower guide layer, an InGaAsP quantum well active layer composed of one or a plurality of well layers and a plurality of barrier layers alternately disposed and an AlGaAs upper guide layer on a GaAs substrate, the method comprising:
a first process in which the lower guide layer and a GaAs lower interface protective layer are sequentially crystal-grown at a first growth temperature;
a second process in which, after the first process, the growth is interrupted, and the growth temperature is lowered to a second growth temperature;
a third process in which, after the second process, the growth is resumed to sequentially grow the quantum well active layer and a GaAs upper interface protective layer;
a fourth process in which, after the third process, the growth is interrupted, and the growth temperature is raised almost to the first growth temperature; and
a fifth process in which, after the fourth process, the growth is resumed to grow the upper guide layer on the GaAs upper interface protective layer.

11. An optical disc unit including the semiconductor laser device of claim 1.
